(19) United States
(12) Patent Application Publication
(10) Pub. No.: US 2025/0309181 A1
(43) Pub. Date: Oct. 2, 2025

(54) FLUID DISPENSING APPARATUS, WAFER BONDING APPARATUS, AND METHOD OF MANUFACTURING SEMICONDUCTOR PACKAGE

(71) Applicant: Taiwan Semiconductor Manufacturing Company, Ltd., Hsinchu (TW)

(72) Inventors: Hau-Yi Hsiao, Chiayi City (TW); Kuo-Ming Wu, Tainan City (TW); Che Wei Yang, New Taipei City (TW); Sheng-Chau Chen, Tainan City (TW); Kuo-Liang Lu, Hsinchu City (TW); Cheng-Yuan Tsai, Hsin-Chu county (TW); Chung-Yi Yu, Hsin-Chu (TW)

(73) Assignee: Taiwan Semiconductor Manufacturing Company, Ltd., Hsinchu (TW)

(21) Appl. No.: 18/625,151

(22) Filed: Apr. 2, 2024

(51) Int. Cl. H01L 23/00; G01N 21/85; H01L 21/304

(52) U.S. Cl. CPC H01L 24/74; G01N 21/85; H01L 24/80; G01N 2201/06113; H01L 21/304; H01L 2224/74; H01L 2224/80007; H01L 2224/80895; H01L 2224/80896; H01L 2924/401

(57) ABSTRACT

A fluid dispensing apparatus includes a workpiece carrier configured to carry a workpiece thereon, a dispensing nozzle disposed at a side of the workpiece carrier and configured to dispense a fluid toward the workpiece along a flow path, a light source disposed at a side of the flow path for emitting light passing through the flow path, a sensor positioned to sense the light from the light source and generating a sensing signal accordingly, and a processor coupled to the sensor and configured to determine an operation status of the dispensing nozzle according to the sensing signal.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged. An example of such packaging systems is Package-on-Package (POP) technology. In a PoP device, a top semiconductor package is stacked on top of a bottom semiconductor package to provide a high level of integration and component density. PoP technology generally enables production of semiconductor devices with enhanced functionalities and small footprints on a printed circuit board (PCB).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a schematic top view of a fluid dispensing apparatus according to some exemplary embodiments of the present disclosure.

FIG. 2A illustrates a schematic side view of a fluid dispensing apparatus dispensing fluid according to some exemplary embodiments of the present disclosure.

FIG. 2B illustrates a partial enlarged view of a wafer stacking structure shown in FIG. 2A according to some exemplary embodiments of the present disclosure.

FIG. 3 illustrates a schematic side view of a fluid dispensing apparatus dispensing fluid according to some exemplary embodiments of the present disclosure.

FIG. 4 illustrate a schematic view of a sealant dispensed on a perimeter of a wafer stacking structure according to some exemplary embodiments of the present disclosure.

FIG. 5 is a diagram illustrating a time chart of optical power intensity detected by an optical sensor of a fluid dispensing apparatus according to some exemplary embodiments of the present disclosure.

FIG. 6 illustrates a schematic view of an image captured by an image capturing device of a fluid dispensing apparatus according to some exemplary embodiments of the present disclosure.

FIG. 7 illustrate a schematic side view of a fluid dispensing apparatus when the dispensing nozzle thereof is clogged according to some exemplary embodiments of the present disclosure.

FIG. 8 is a diagram illustrating a time chart of an optical power intensity detected by an optical sensor of a fluid dispensing apparatus when the dispensing nozzle thereof is clogged according to some exemplary embodiments of the present disclosure.

FIG. 9 illustrates a schematic view of an image captured by an image capturing device of a fluid dispensing apparatus when the dispensing nozzle thereof is clogged according to some exemplary embodiments of the present disclosure.

FIG. 10 illustrates a schematic side view of a fluid dispensing apparatus dispensing fluid according to some exemplary embodiments of the present disclosure.

FIG. 11 illustrates a schematic side view of a fluid dispensing apparatus dispensing fluid according to some exemplary embodiments of the present disclosure.

FIG. 12 and FIG. 13 illustrates schematic views of images captured by an image capturing device of a fluid dispensing apparatus when the dispensing nozzle is in an abnormal operation status according to some exemplary embodiments of the present disclosure.

FIG. 14 illustrates a schematic view of intermediate stages in the manufacturing of a semiconductor package according to some exemplary embodiments of the present disclosure.

FIG. 15 illustrates a process flow of a method of manufacturing a semiconductor package according to some exemplary embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

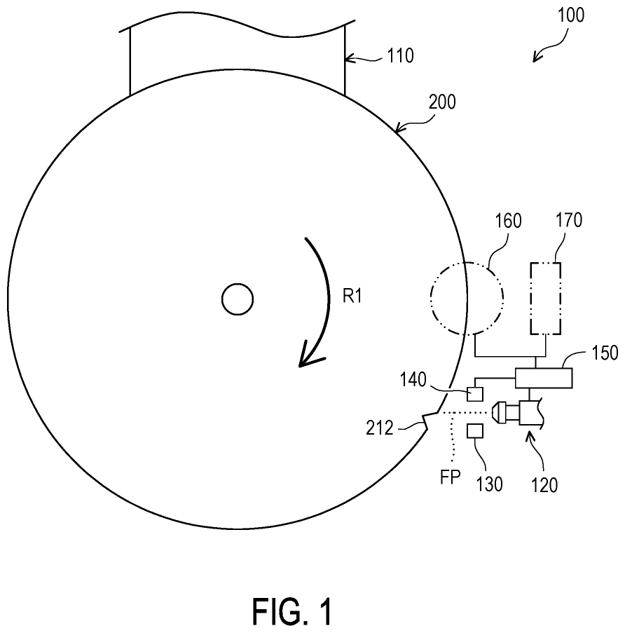

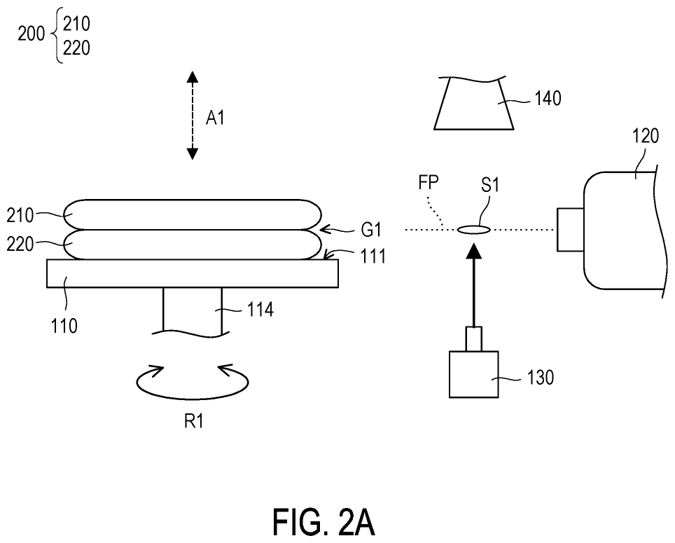

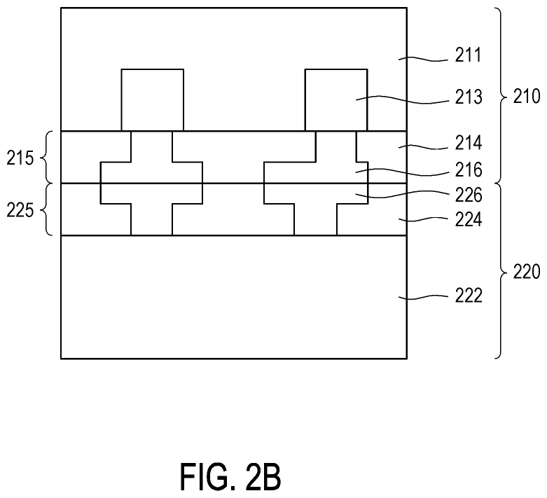

FIG. 1 illustrates a schematic top view of a fluid dispensing apparatus according to some exemplary embodiments of the present disclosure. FIG. 2A illustrates a schematic side view of a fluid dispensing apparatus dispensing fluid according to some exemplary embodiments of the present disclosure. Referring to FIG. 1 and FIG. 2A, in some embodiments, a fluid dispensing apparatus 100 including a workpiece carrier 110, a dispensing nozzle 120, a light source 130, a sensor 140, and a processor 150 is provided. The workpiece carrier 110 is configured to carry a workpiece 200 thereon. The dispensing nozzle 120 is disposed at a side of the workpiece carrier 110 and configured to dispense a fluid S1 toward the workpiece 200 along a flow path FP. In the present embodiment, the fluid dispensing apparatus 100 may be a wafer bonding apparatus 100, and the workpiece 200 may be a wafer stacking structure 200, which may include a first wafer 210 stacked over a second wafer 220. However, the disclosure is not limited thereto. In other embodiment, the fluid dispensing apparatus 100 can be configured to dispense any suitable fluid toward any suitable workpiece such as dispensing photoresist or underfill over a substrate, for example.

FIG. 2B illustrates a partial enlarged view of a wafer stacking structure shown in FIG. 2A according to some exemplary embodiments of the present disclosure. It is noted that FIG. 2B illustrates a partial enlarged view of a cross section Cl of the wafer stack structure 200 shown in FIG. 2A. Referring to FIG. 2A and FIG. 2B, in accordance with some embodiments of the disclosure, the first wafer 210 and the second wafer 220 are shown being bonded in accordance with an embodiment of the present disclosure. The first wafer 210 and the second wafer 220 include a first semiconductor substrate 211 and a second semiconductor substrate 222 respectively, with electronic circuitry (not shown) formed thereon. The first semiconductor substrate 211 and the second semiconductor substrate 222 may each include bulk silicon, doped or undoped, or an active layer of a semiconductor-on-insulator (SOI) substrate. Generally, an SOI comprises a layer of a semiconductor material, such as silicon, formed on an insulator layer. The insulator layer may be, for example, a buried oxide (BOX) layer or a silicon oxide layer. The insulator layer is provided on a substrate, typically a silicon or glass substrate. Other substrates, such as a multi-layered or gradient substrate may also be used.

The circuitry formed on the substrate may be any type of circuitry suitable for a particular application. In an embodiment, the circuitry includes electrical devices formed on the substrate with one or more dielectric layers overlying the electrical devices. Metal layers may be formed between dielectric layers to route electrical signals between the electrical devices. Electrical devices may also be formed in the one or more dielectric layers.

For example, the circuitry may include various N-type metal-oxide semiconductor (NMOS) and/or P-type metal-oxide semiconductor (PMOS) devices, such as transistors, capacitors, resistors, diodes, photo-diodes, fuses, and the like, interconnected to perform one or more functions. The functions may include memory structures, processing structures, sensors, amplifiers, power distribution, input/output circuitry, or the like. One of ordinary skill in the art will appreciate that the above examples are provided for illustrative purposes only to further explain applications of the present invention and are not meant to limit the present invention in any manner. Other circuitry may be used as appropriate for a given application.

In some embodiments, the first wafer 210 and the second wafer 220 include a first interconnect layer 215 and a second interconnect layer 225, respectively, formed thereon. The first interconnect layer 215 includes contacts 216 formed in one or more dielectric layers 214. Correspondingly, the second interconnect layer 225 includes contacts 226 formed in one or more dielectric layers 224. Generally, the one or more dielectric layers 214, 224 may be formed, for example, of a low-K dielectric material, silicon oxide, phosphosilicate glass (PSG), borophosphosilicate glass (BPSG), fluorinated silicate glass (FSG), or the like, by any suitable method known in the art. In an embodiment, the one or more dielectric layers 214, 224 include an oxide that may be formed by chemical vapor deposition (CVD) techniques using tetra-ethyl-ortho-silicate (TEOS) and oxygen as a precursor. Other materials and processes may be used. It should also be noted that the dielectric layers 214, 224 may each include a plurality of dielectric layers, with or without an etch stop layer formed between dielectric layers.

The contacts 216, 226 may be formed in the dielectric layers 214, 224 respectively by any suitable process, including photolithography and etching techniques. Generally, photolithography techniques involve depositing a photoresist material, which is masked, exposed, and developed to expose portions of the dielectric layers 214, 224 that are to be removed. The remaining photoresist material protects the underlying material from subsequent processing steps, such as etching. In the preferred embodiment, photoresist material is utilized to create a patterned mask to define contacts 216, 226. The etching process may be an anisotropic or isotropic etch process, but preferably is an anisotropic dry etch process. After the etching process, any remaining photoresist material may be removed. Processes that may be used to form the contacts 216, 226 include single and dual damascene processes.

The contacts 216, 226 may be formed of any suitable conductive material, but is preferably formed of a highly-conductive, low-resistive metal, elemental metal, transition metal, or the like. Furthermore, the contacts 216, 226 may include a barrier/adhesion layer to prevent diffusion and provide better adhesion between the contacts 216, 226 and the dielectric layers 214, 224. A chemical-mechanical polishing (CMP) process may be performed to planarize the surface of the first wafer 210 and the second wafer 220.

It should be noted that in the embodiment illustrated in FIG. 1, the contacts 226 formed on the second wafer 220 may connect to any type of semiconductor structure (not shown), such as transistors, capacitors, resistors, or the like, or an intermediate contact point, such as a metal interconnect or the like.

Also illustrated in FIG. 2B are through-silicon vias (TSVs) 213 formed in the first semiconductor substrate 211. The TSVs 213 may be formed of any suitable conductive material, but are preferably formed of a highly-conductive, low-resistive metal, elemental metal, transition metal, or the like. For example, in an embodiment the TSVs are filled with Cu, W, or the like. The TSVs 213 are electrically coupled to respective ones of the contacts 216 on the first wafer 210. As will be discussed below, the first wafer 210 will be thinned, thereby exposing the TSVs 213.

In accordance with some embodiments of the disclosure, a bonding process is performed to the first wafer 210 and the second wafer 220 to form the wafer stacking structure 200 shown in FIG. 2B. The bonding process may include any suitable bonding procedure for the specific application and materials. For example, direct bonding, metal diffusion, anodic, oxide fusion bonding, and the like bonding methods may be performed. In an embodiment, a conductive metal or metal alloy, such as Cu, W, CuSn, AuSn, InAu, PbSn, or the like, is utilized as a bonding material to directly bond contacts on the first wafer 104 to the corresponding contacts on the second wafer 106. In another embodiment, a polymer, such as bis-benzocyclobutene (BCB), epoxy, an organic glue, or the like, is utilized as a bonding material. In this embodiment, the bonding material may be applied to the dielectric layer 214, 224 of the first wafer 210 and/or the second wafer 220.

FIG. 2A illustrates a larger portion of the wafer stacking structure 200 after the bonding procedure discussed above has been performed in accordance with an embodiment of the present invention. One of ordinary skill in the art, however, will realize that FIG. 2A is a simplification of the wafer stacking structure 200 and that the actual bonding mechanism used may vary in, for example, application, materials, shape, size, and the like. FIG. 2A also illustrates that edges of the first wafer 210 and the second wafer 220 are generally non-perpendicular, beveled, or rounded. As a result, the wafer edge of the first (upper) wafer 210 is not supported by the edge of the second (lower) wafer 220 and may break off or peel off during a thinning process subsequently performed on the first wafer 210.

Accordingly, the fluid dispensing apparatus 100 is provided to dispense sealant (e.g., adhesive) toward a bonding interface between the first wafer 210 and the second wafer 220 to fill the gap G1 between the first wafer 210 and the second wafer 220 and provide support to the first wafer 210 during the thinning process. In some embodiments, the sealant S1 may include a high heat resistant material that has been applied and cured in a vacuum. It should be noted that the sealant S1 is illustrated as a single layer for illustrative purposes only and may include a plurality of layers of different materials. Suitable materials that may be used to form the sealant S1 include polyimide, BCB, SOG, SiOx, SiNx, SiONx, other inorganic materials, other silicon-related materials, other high thermal stable polymers, and the like.

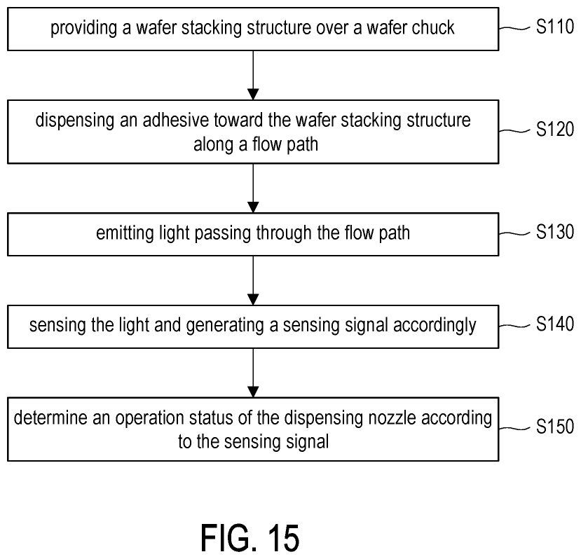

FIG. 15 illustrates a process flow of a method of manufacturing a semiconductor package according to some exemplary embodiments of the present disclosure. Referring to FIG. 2A and FIG. 15, the method of manufacturing a semiconductor package may include the following steps. In some embodiments, step S110 is performed where the wafer stacking structure 200 is provided over the wafer chuck 110. In detail, the first wafer 104 and the second wafer 106 are bonded together and placed on the wafer chuck (e.g., workpiece carrier) 110. The wafer chuck 110 is supported by rotating shaft 114 and configured to rotate along a rotating direction R1 about an axis A1 substantially perpendicular to a carrying surface 111 of the wafer chuck 110. In some embodiments, the wafer stacking structure 200 may be placed on the wafer chuck 110 through a pick and place tool such as a robot arm.

In some embodiments, a scanning process may be performed on the wafer stacking structure 200 in order to obtain the position information of the bonding interface (i.e., gap G1) of the wafer stacking structure 200 where the sealant S1 is to be dispensed thereon. Accordingly, a plurality of image capturing devices may be provided for capturing a plurality of images of the wafer stacking structure 200 to obtain the position information of the gap G1. The image capturing devices may include a top-view lens 160 placed above the wafer chuck 110 and capturing the horizontal position information of the gap G1 to be glued, and a side-view lens 170 placed on the side of the wafer chuck 110 to obtain the vertical position information of the gap G1. In this embodiment, preferably, the above-mentioned step of acquiring position information includes rotating the workpiece 360 degrees on the wafer chuck 110, and transmitting the above-mentioned position information to a recording and processor 150.

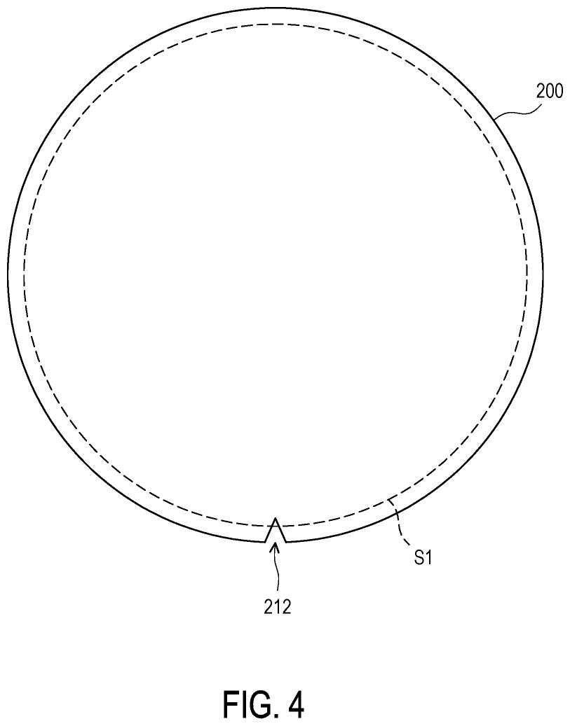

Then, step S120 is performed where the sealant S1 is dispensed toward the wafer stacking structure 200 along a flow path FP. The dispensing nozzle 120 is disposed at a side of the wafer chuck 110 and configured to dispense the sealant (e.g., adhesive, or any suitable fluid) S1 toward the wafer stacking structure 200 along the flow path FP, such that the sealant S1 may be injected along the wafer edges between the first wafer 210 and the second wafer 220 and filling the gap G1 around a perimeter of the wafer stacking structure 200 as the wafer chuck 110 is rotated along the rotating direction R1. Accordingly, the flow path FP is substantially parallel to the carrying surface 111 of the wafer chuck 110, which means the dispensing nozzle 120 is positioned to dispense the sealant S1 horizontally toward the bonding interface between the first wafer 210 and the second wafer 220, and the rotation of the wafer stacking structure 200 may help smooth and seal the sealant S1 along the wafer edges. Referring to FIG. 4, in some embodiments, the dispensing nozzle 120 may dispense the sealant S1 periodically, so the sealant S1 dispensed along perimeter of the wafer stacking structure 200 may not be a close circle, but a dotted line surrounding the perimeter of the wafer stacking structure 200 as shown in FIG. 4.

Referring to FIG. 1 and FIG. 4, in some embodiments, a starting point of the wafer stacking structure 200 for starting dispensing the sealant S1 may be set based on the position information obtained by the image capturing devices 160, 170. In the present embodiment, the starting point can be determined based on the identification mark (e.g., identification notch) 212 of the wafer stacking structure 200. In the embodiment, the notch is used for illustrative purpose, but it also applies to other identifying marks with flat edges. Then, the identification mark 212 of the wafer stacking structure 200 is aligned with the dispensing nozzle 120 for starting the dispensing process.

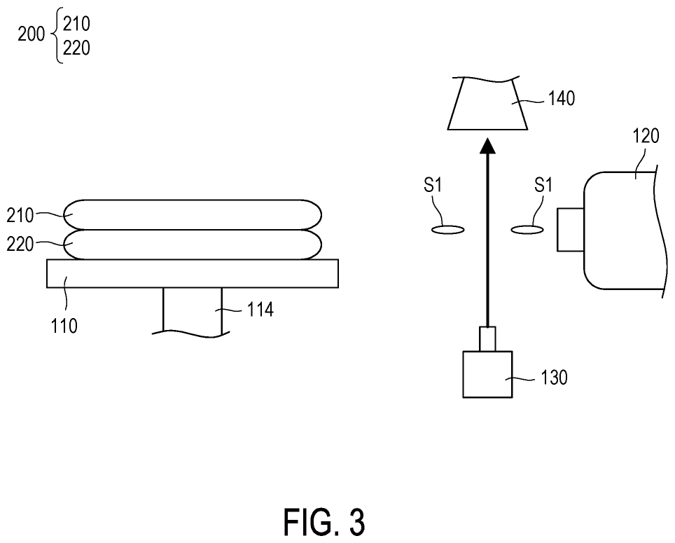

FIG. 3 illustrates a schematic side view of a fluid dispensing apparatus dispensing fluid according to some exemplary embodiments of the present disclosure. Referring to FIG. 2A and FIG. 3, in order to monitor an operation status of the dispensing nozzle 120 to identify the situation of the dispensing nozzle 120 being clogged, the light source 130 and the sensor 140 are provided by the flow path FP of the sealant. Accordingly, step S130 is performed where the light emitted by the light source 130 passes through the flow path FP, and then step S140 is performed where the light is received by the sensor 140, so that the sensor generates a sensing signal accordingly. In detail, referring to FIG. 2A and FIG. 3, the light source 130 is disposed at a side of the flow path FP for emitting light passing through the flow path FP, and the sensor 140 is positioned to sense the light from the light source 130 and generates a sensing signal accordingly. The light source 130 may include a light emitting diode (LED), a laser diode, or any other suitable light source. In the embodiment, the light source 130 is a laser point source, but the disclosure is not limited thereto. The light source 130 is configured to illuminate the flow path FP. The sensor 140 may include image sensors such as, charged coupled devices (CCDs), optical sensors such as photomultiplier tubes (PMTs), optical power meters, or any other suitable type of image or optical sensors. The sensor 140 is positioned to sense the light from the light source 130. In the embodiment, the light source 130 and the sensor 140 are disposed on two opposite sides of the flow path FP respectively. In other words, the light source 130 and the sensor 140 can be seen as a droplet detector. The light source 130 and the sensor 140 may be placed to face one another across the flow path FP through which the sealant S1 injected from the dispensing nozzle 120 travels. The direction in which the light source 130 and the sensor 140 face one another may be orthogonal to the flow path FP.

In the embodiment of the sensor 140 being an optical sensor such as a power meter, the sensor 140 may receive the continuous light beam emitted from the light source 130 and detect the optical intensity the continuous light beam. In some embodiments, the sensor 140 may be a light receiving element including a photodiode. The sensor 140 may detect the optical intensity of the continuous light. The sensor 140 may be coupled to the processor 150. The sensor 140 may output a sensing signal indicating the detected optical intensity to the processor 150.

In the embodiment of the sensor 140 being an image sensor 140, the image sensor 140 may capture the image of the droplets of the sealant S1 travels along the flow path FP and generate the image data accordingly. The image sensor 140 captures the image of the shadow of the droplets irradiated with the light from the light source 130. In some embodiments, the image sensor 140 may be a two-dimensional image sensor such as a CCD (charge-coupled device). The image sensor 140 may include a shutter (not shown). The shutter may be an electric shutter or a mechanical shutter. The image sensor 140 may be coupled to the processor 150, and the image sensor 140 may generate the image data of the image of the droplet of the sealant S1 (e.g., the image shown in FIG. 6) captured. The image sensor 140 may output the generated image data to the processor 150.

Then, step S150 is performed where an operation status of the dispensing nozzle is determined according to the sensing signal. In detail, When the droplets of the sealant S1 passes through the predetermined position on the flow path FP, the optical intensity of the continuous light beam detected by the sensor 140 is reduced because the continuous light beam is blocked by the droplets of the sealant S1. The sensor 140 may output the sensing signal responsive to the reduction in the optical intensity due to the passage of the droplets of the sealant S1, to the processor 150. Here, the sensing signal responsive to the reduction in the optical intensity due to the passage of the droplets of the sealant S1 may be referred to as “droplet detection signal.”

The light from the light source 130 intersects the droplets of the sealant S1 on the flow path FP, so the light beam is scattered by the droplets of the sealant S1. That is, at least some part of the light from the light source 130 intersecting the droplets of the sealant S1 will be scattered at an angle and deviated from the original flow path FP (referred to herein as side scatter light). The droplet of the sealant S1 may have any diameter for example, 50 μm, 70 μm, 100 μm, or any other suitable diameter. The nozzle diameter will affect the properties of a flow stream, such as the stream dimensions, droplet break-off point and drop volume. In some embodiments, the inner diameter of the dispensing nozzle ranges from about 0.05 mm to about 50 μm. To view the flow path FP, the light source 130 may optionally utilized and be positioned around the region of the flow path FP. In the embodiments, the injection flow of the sealant S1 is a series of droplets, but in other embodiments, the injection flow of the sealant S1 may be a continuous stream.

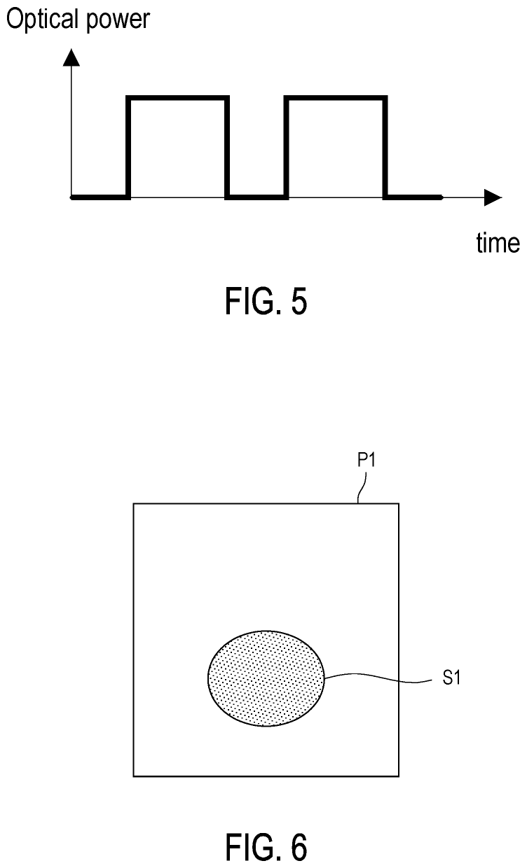

FIG. 5 is a diagram illustrating a time chart of optical power intensity detected by an optical sensor of a fluid dispensing apparatus according to some exemplary embodiments of the present disclosure. Referring to FIG. 2A, FIG. 3, and FIG. 5, in the embodiment of the sensor 140 being an optical sensor, the optical intensity of the continuous light detected by the optical sensor 140 may have peaks and valleys since the injection flow of the sealant S1 is a series of droplets. When the droplets of the sealant S1 intersects the light from the light source 130 as it is shown in FIG. 2A, the optical intensity of the light detected by the optical sensor 140 would be lower, i.e. the valley of the curve shown in FIG. 5. When there's no droplet intersects the light from the light source 130 as it is shown in FIG. 3, the optical intensity of the light detected by the optical sensor 140 would be higher, i.e. the peak of the curve shown in FIG. 5. Accordingly, when the dispensing nozzle 120 is in a normal operation status, i.e., no clogging, the peaks and valleys of the curve of the optical intensity detected by the sensor 140 should appear alternately and periodically according to the injection frequency of the dispensing nozzle 120. Therefore, the processor 150 can determine the dispensing nozzle 120 is in a normal operation status when the sensor 140 senses a blockage of the light from the light source 130 periodically, which means the optical sensor 140 detects the valleys (lower optical intensity) of the optical intensity of the light from the light source 130 periodically.

FIG. 6 illustrates a schematic view of an image captured by an image capturing device of a fluid dispensing apparatus according to some exemplary embodiments of the present disclosure. Referring to FIG. 2A, and FIG. 6, in the embodiment of the sensor 140 being an image sensor, the sensor 140 may be positioned to capture an image of the flow path FP in its detection field. When the droplets of the sealant S1 intersects the light from the light source 130 as it is shown in FIG. 2A, the image P1 of the shadow of the droplet of the sealant S1 captured by the image sensor 140 is shown in FIG. 6. When there's no droplet intersects the light from the light source 130 as it is shown in FIG. 3, the image captured by the image sensor 140 may be completely blank as it is shown in FIG. 9. Accordingly, when the dispensing nozzle 120 is in a normal operation status, i.e., no clogging, the image of the droplet of the sealant S1 captured by the image sensor 140 should appear periodically according to the injection frequency of the dispensing nozzle 120. Therefore, the processor 150 can determine the dispensing nozzle 120 is in a normal operation status when the sensor 140 senses a blockage of the light from the light source 130 periodically, which means the image sensor 140 captures the shadow of the sealant droplet periodically.

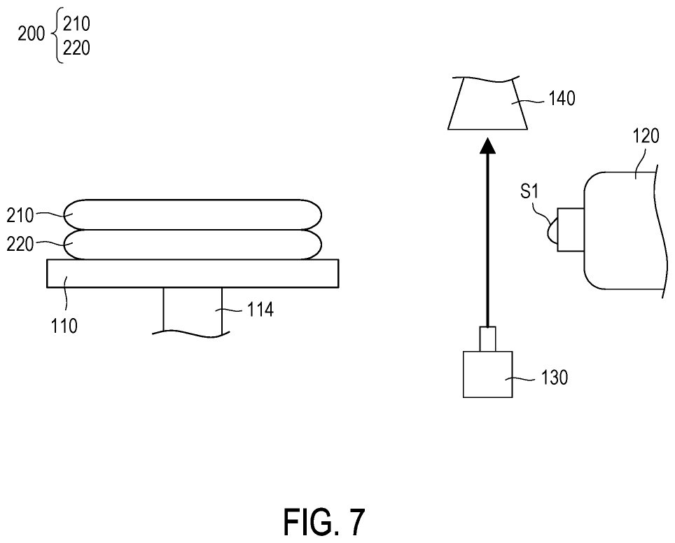

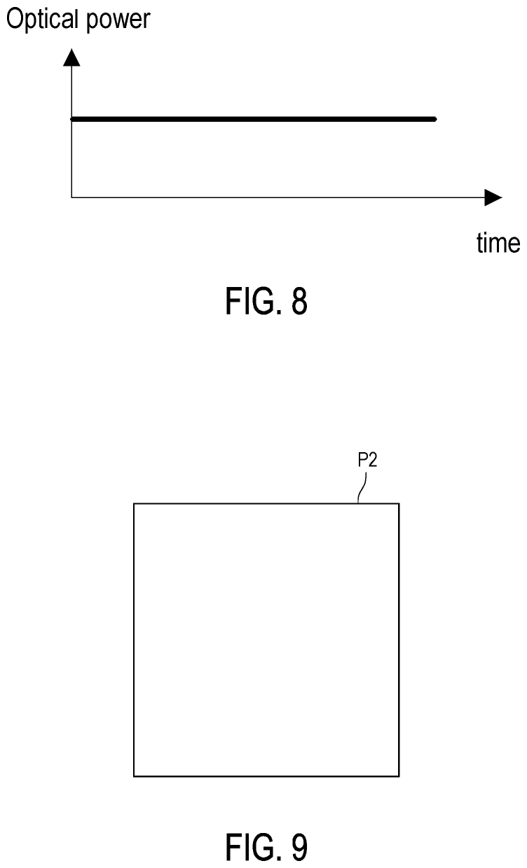

FIG. 7 illustrate a schematic side view of a fluid dispensing apparatus when the dispensing nozzle thereof is clogged according to some exemplary embodiments of the present disclosure. FIG. 8 is a diagram illustrating a time chart of an optical power intensity detected by an optical sensor of a fluid dispensing apparatus when the dispensing nozzle thereof is clogged according to some exemplary embodiments of the present disclosure. Referring to FIG. 7 and FIG. 8, when the dispensing nozzle 120 is in an abnormal operation status, e.g., the dispensing nozzle being completely clogged as shown in FIG. 7, there would be no droplets of the sealant S1 intersect the continuous light from the light source 130 over a certain period of time. Accordingly, in the embodiment of the sensor 140 being an optical sensor, the optical intensity of the light detected by the optical sensor 140 would be constantly at a peak value as shown in FIG. 8. Therefore, the processor 150 can determine the dispensing nozzle 120 is in an abnormal operation status when the sensor 140 senses a constant optical intensity of the light from the light source 130 over a predetermined period of time (e.g., longer than the injection frequency of the dispensing nozzle 120).

FIG. 9 illustrates a schematic view of an image captured by an image capturing device of a fluid dispensing apparatus when the dispensing nozzle thereof is clogged according to some exemplary embodiments of the present disclosure. Referring to FIG. 7 and FIG. 9, when the dispensing nozzle 120 is in an abnormal operation status, e.g., the dispensing nozzle being completely clogged as shown in FIG. 7, there would be no droplets of the sealant S1 intersect the continuous light from the light source 130 over a certain period of time. Accordingly, the image sensor 140 cannot capture any image of the droplet of the sealant S1, so the image P2 captured by the image sensor 140 may be completely blank as it is shown in FIG. 9. Accordingly, when the dispensing nozzle 120 is in an abnormal operation status, e.g., the dispensing nozzle being completely clogged as shown in FIG. 7, the image captured by the image sensor 140 should appear blank over a predetermined period of time (e.g., longer than the injection frequency of the dispensing nozzle 120). Therefore, the processor 150 can determine the dispensing nozzle 120 is in an abnormal operation status when the sensor 140 senses a constant optical intensity of the light from the light source 130 and capturing a constant blank image over a predetermined period of time (e.g., longer than the injection frequency of the dispensing nozzle 120).

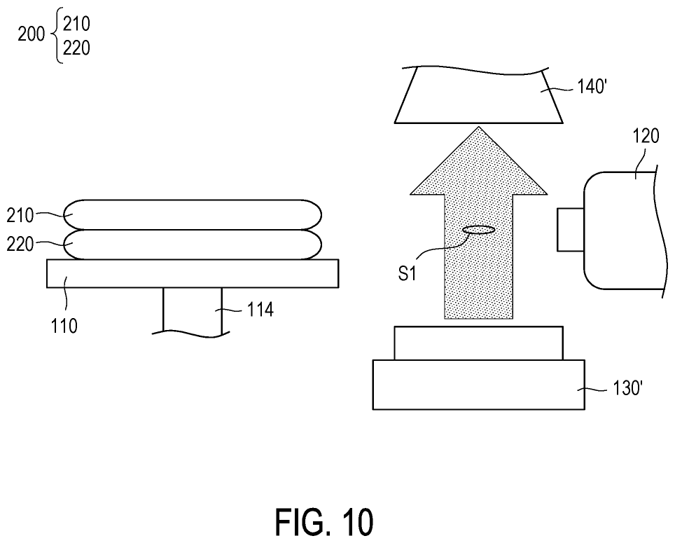

FIG. 10 illustrates a schematic side view of a fluid dispensing apparatus dispensing fluid according to some exemplary embodiments of the present disclosure. It is noted that the fluid dispensing apparatus in FIG. 10 contains many features same as or similar to the fluid dispensing apparatus disclosed in the previous embodiments. For purpose of clarity and simplicity, detail description of same or similar features may be omitted, and the same or similar reference numbers denote the same or like components.

Referring to FIG. 10, in some embodiments, the light source 130′ may include a laser line scanner so as to expand the illuminating range of the light source. That is, the light source 130′ may include a laser light source such as a laser pointer and any arrangement of components to distribute a line of laser light to provide a plane of laser illumination. This may include any suitable active or passive optical elements such as a lens that distributes light across a plane, or moving mirror or other mechanism that oscillates to direct the light across the plane. Thus it will be understood that the term “line” as used herein may refer to an actual line, e.g., through an optical spreader, or a laser dot that moves through a line with sufficient speed to permit capture of a line with the sensor 140′. Similarly, a laser line may include a line or any number and arrangement of laser dots capable of achieving similar affects. Correspondingly, the sensor 140′ may be a line sensor for receiving the laser line from the light source 130′.

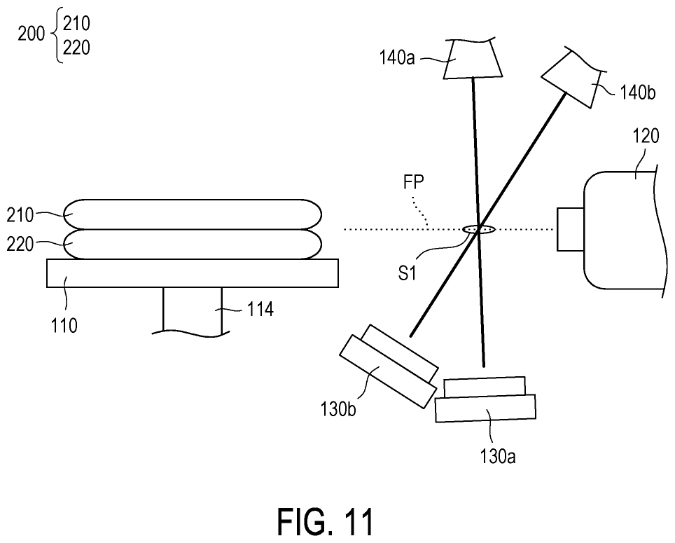

FIG. 11 illustrates a schematic side view of a fluid dispensing apparatus dispensing fluid according to some exemplary embodiments of the present disclosure. It is noted that the fluid dispensing apparatus in FIG. 11 contains many features same as or similar to the fluid dispensing apparatus disclosed in the previous embodiments. For purpose of clarity and simplicity, detail description of same or similar features may be omitted, and the same or similar reference numbers denote the same or like components.

Referring to FIG. 11, in some embodiments, the light source may include a plurality of light sources 130a, 130b, i.e., a first light source 130a and a second light source 130b. Correspondingly, the sensor may include a plurality of sensors 140a, 140b, i.e., a first sensor 140a and a second sensor 140b, oriented with the first light source 130a and a second light source 130b respectively. In some embodiments, a first light from the first light source 130a is intersected with a second light from the second light source 130b, and the intersection of the first light and the second light is on the flow path FP. That is, the first light and the second light are intersected with the flow path FP. In one embodiment, the first light source 130a and a second light source 130b may be laser line scanners to increase the intersecting region thereof and make it easier to align with one another. In other embodiment, the first light source 130a and a second light source 130b may be laser point source, or the like. It is noted that two sets of light sources and sensors are illustrated herein, but the disclosure is not limited thereto. The fluid dispensing apparatus may include more sets of light sources and sensors as long as they intersect with one another and intersect with the flow path FP. In this embodiment, the sensors 140a, 140b are image sensors for capturing images of the droplet of the sealant S1 from different view angles.

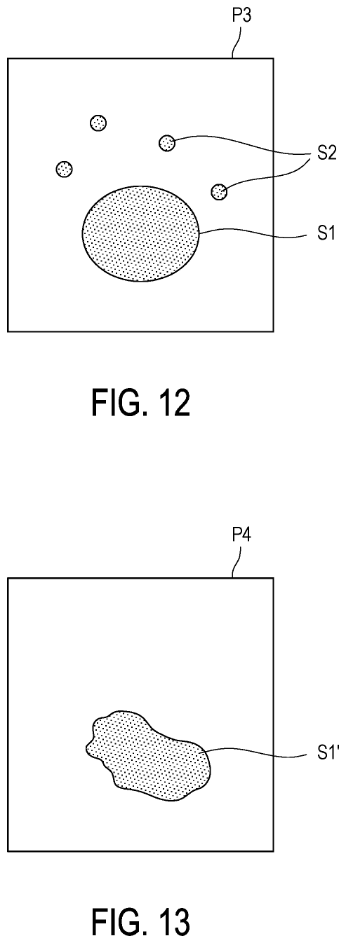

FIG. 12 and FIG. 13 illustrates schematic views of images captured by an image capturing device of a fluid dispensing apparatus when the dispensing nozzle is in an abnormal operation status according to some exemplary embodiments of the present disclosure. Referring to FIG. 11 to FIG. 13, in some situations, the dispensing nozzle 120 may not be completely clogged but just partially clogged, so the droplet of sealant S1 may still be able to be injected from the dispensing nozzle 120 at normal injection frequency, but the shapes of the droplet may be different from the normal pattern. Therefore, by arranging multiple image sensors 130a, 130b for capturing images of the droplet from different angles, the situation of the dispensing nozzle 120 being partially clogged can be easily spotted. For example, in one embodiment, when the dispensing nozzle 120 is partially clogged, apart from the main droplet of the sealant S1, there might be other scattered droplets S2 scattering around the main droplet S1 as it is shown in the image P3 of FIG. 12. In other embodiment, when the dispensing nozzle 120 is partially clogged, the droplet of the sealant S1′ may be in an irregular shape instead of a circular shape as it is shown in the image P4 of FIG. 13. The processor 150 may compare the images of the droplet from the sensors 140a, 140b to see whether the droplet pattern is different from a baseline pattern to determine whether the dispensing nozzle 120 is in an abnormal operation status. Similar for the embodiment of the sensors 140a, 140b being optical sensors, the optical intensity of the light from the light sources 130a, 130b detected by the sensors 140a, 140b may be different from a baseline intensity when the dispensing nozzle 120 is partially clogged. Therefore, the processor 150 can determine the dispensing nozzle 120 is in an abnormal operation status (the dispensing nozzle 120 being partially clogged) when the sensor senses the light from the light source has a different intensity or pattern from a baseline intensity or pattern. The processor 150 may trigger an alarm or control a user interface to display warning message. Therefore, the issue of the dispensing nozzle 120 being clogged resulting in uneven dispensing of the sealant S1 can be avoided.

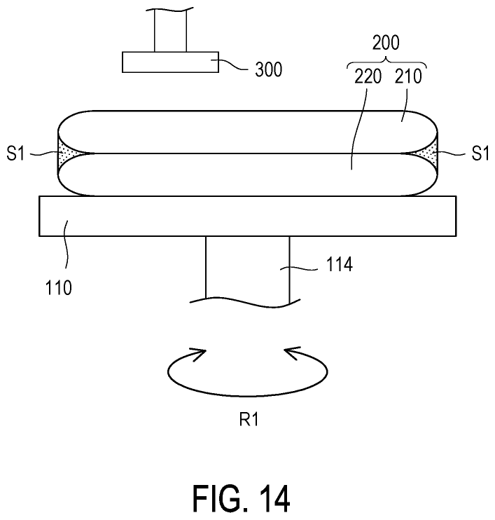

FIG. 14 illustrates a schematic view of intermediate stages in the manufacturing of a semiconductor package according to some exemplary embodiments of the present disclosure. After the sealant S1 is evenly dispensed on the wafer stacking structure 200 to fill the gap between the first wafer 210 and the second wafer 210, a thinning process can be performed on a back surface of the wafer stacking structure 200. In the embodiment illustrated in FIG. 14, the thinning process includes using a grinder 300 in a grinding process to reduce the thickness of the first wafer 210. One of ordinary skill in the art will realize that other thinning processes, such as a polish process (including a wet polish (CMP) and a dry polish), a plasma etch process, a wet etch process, or the like, may also be used.

It should be noted that the thinning process exposes the TSVs 213 (shown in FIG. 2B). In this manner, after the thinning process, the TSVs 213 extend through the substrate 211 to provide an electrical connection to circuitry included on the second wafer 220 through the first wafer 210. With the sealant S1 filling the gap between the first wafer 210 and the second wafer 210, the wafer edge of the first (upper) wafer 210 is supported by the sealant S1 during a thinning process subsequently performed on the first wafer 210. As one of ordinary skill in the art will appreciate, the sealant S1 provides additional support for the wafer edges during the thinning process, thereby preventing or reducing cracking or chipping. As a result, higher yields may be obtained, reducing costs and increasing revenues.

Based on the above discussions, it can be seen that the present disclosure offers various advantages. It is understood, however, that not all advantages are necessarily discussed herein, and other embodiments may offer different advantages, and that no particular advantage is required for all embodiments.

In accordance with some embodiments of the disclosure, a fluid dispensing apparatus includes a workpiece carrier configured to carry a workpiece thereon, a dispensing nozzle disposed at a side of the workpiece carrier and configured to dispense a fluid toward the workpiece along a flow path, a light source disposed at a side of the flow path for emitting light passing through the flow path, a sensor positioned to sense the light from the light source and generating a sensing signal accordingly, and a processor coupled to the sensor and configured to determine an operation status of the dispensing nozzle according to the sensing signal. In one embodiment, the workpiece carrier is configured to rotate about an axis substantially perpendicular to a carrying surface of the workpiece carrier. In one embodiment, the flow path is substantially parallel to the carrying surface of the workpiece carrier. In one embodiment, the light source comprises a laser point source, or a laser line scanner. In one embodiment, the sensor comprises an image, or an optical sensor. In one embodiment, the light source and the sensor are disposed on two opposite sides of the flow path respectively. In one embodiment, the light source comprises a plurality of light sources and the sensor comprises a plurality of sensors oriented with the plurality of light sources respectively. In one embodiment, a first light from one of the plurality of light sources is intersected with a second light from another one of the plurality of light sources. In one embodiment, an intersection of the first light and the second light is on the flow path.

In accordance with some embodiments of the disclosure, a wafer bonding apparatus includes a wafer chuck configured to carry a wafer stacking structure thereon, a dispensing nozzle disposed at a side of the wafer chuck and configured to dispense an sealant toward the wafer stacking structure along a flow path, a light source configured to emit light passing through the flow path, a sensor positioned to sense the light from the light source and generating a sensing signal accordingly, and a processor coupled to the sensor and configured to determine an operation status of the dispensing nozzle according to the sensing signal. In one embodiment, the flow path is substantially parallel to a carrying surface of the wafer chuck. In one embodiment, the wafer stacking structure comprises a first wafer stacked over a second wafer. In one embodiment, the dispensing nozzle is configured to dispense the sealant toward a bonding interface between the first wafer and the second wafer. In one embodiment, the light source comprises a plurality of light sources and the sensor comprises a plurality of sensors oriented with the plurality of light sources respectively. In one embodiment, a first light from one of the plurality of light sources is intersected with a second light from another one of the plurality of light sources, and an intersection of the first light and the second light is on the flow path.

In accordance with some embodiments of the disclosure, a method of manufacturing a semiconductor package includes the following steps: providing a wafer stacking structure over a wafer chuck; dispensing a sealant toward the wafer stacking structure along a flow path; emitting light passing through the flow path; sensing the light and generating a sensing signal accordingly; and determine an operation status of the dispensing nozzle according to the sensing signal. In one embodiment, the wafer stacking structure comprises a first wafer stacked over a second wafer, and dispensing the sealant toward the wafer stacking structure along the flow path further includes: dispensing the sealant toward a bonding interface between the first wafer and the second wafer along the flowing path substantially parallel to the carrying surface of the wafer chuck. In one embodiment, determine the operation status of the dispensing nozzle according to the sensing signal further includes: determining the dispensing nozzle is in a normal operation status when the sensor senses a blockage of the light from the light source periodically. In one embodiment, determine the operation status of the dispensing nozzle according to the sensing signal further includes: determining the dispensing nozzle is in an abnormal operation status when the sensor senses a constant optical intensity of the light from the light source over a predetermined period of time, or senses the light from the light source has a different intensity or pattern from a baseline intensity or pattern. In one embodiment, the method further includes: performing a thinning process on a back surface of the wafer stacking structure after the sealant is dispensed on the wafer stacking structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A fluid dispensing apparatus, comprising:
a workpiece carrier configured to carry a workpiece thereon;
a dispensing nozzle disposed at a side of the workpiece carrier and configured to dispense a fluid toward the workpiece along a flow path;
a light source disposed at a side of the flow path for emitting light passing through the flow path;
a sensor positioned to sense the light from the light source and generating a sensing signal accordingly;
a processor coupled to the sensor and configured to determine an operation status of the dispensing nozzle according to the sensing signal.

2. The fluid dispensing apparatus as claimed in claim 1, wherein the workpiece carrier is configured to rotate about an axis substantially perpendicular to a carrying surface of the workpiece carrier.

3. The fluid dispensing apparatus as claimed in claim 1, wherein the flow path is substantially parallel to the carrying surface of the workpiece carrier.

4. The fluid dispensing apparatus as claimed in claim 1, wherein the light source comprises a laser point source, or a laser line scanner.

5. The fluid dispensing apparatus as claimed in claim 1, wherein the sensor comprises an image, or an optical sensor.

6. The fluid dispensing apparatus as claimed in claim 1, wherein the light source and the sensor are disposed on two opposite sides of the flow path respectively.

7. The fluid dispensing apparatus as claimed in claim 1, wherein the light source comprises a plurality of light sources and the sensor comprises a plurality of sensors oriented with the plurality of light sources respectively.

8. The fluid dispensing apparatus as claimed in claim 7, wherein a first light from one of the plurality of light sources is intersected with a second light from another one of the plurality of light sources.

9. The fluid dispensing apparatus as claimed in claim 8, wherein an intersection of the first light and the second light is on the flow path.

10. A wafer bonding apparatus, comprising:
a wafer chuck configured to carry a wafer stacking structure thereon;
a dispensing nozzle disposed at a side of the wafer chuck and configured to dispense a sealant toward the wafer stacking structure along a flow path;
a light source configured to emit light passing through the flow path;
a sensor positioned to sense the light from the light source and generating a sensing signal accordingly; and
a processor coupled to the sensor and configured to determine an operation status of the dispensing nozzle according to the sensing signal.

11. The wafer bonding apparatus as claimed in claim 10, wherein the flow path is substantially parallel to a carrying surface of the wafer chuck.

12. The wafer bonding apparatus as claimed in claim 10, wherein the wafer stacking structure comprises a first wafer stacked over a second wafer.

13. The wafer bonding apparatus as claimed in claim 12, wherein the dispensing nozzle is configured to dispense the sealant toward a bonding interface between the first wafer and the second wafer.

14. The wafer bonding apparatus as claimed in claim 10, wherein the light source comprises a plurality of light sources and the sensor comprises a plurality of sensors oriented with the plurality of light sources respectively.

15. The wafer bonding apparatus as claimed in claim 14, wherein a first light from one of the plurality of light sources is intersected with a second light from another one of the plurality of light sources, and an intersection of the first light and the second light is on the flow path.

16. A method of manufacturing a semiconductor package, comprising:
providing a wafer stacking structure over a wafer chuck;
dispensing a sealant toward the wafer stacking structure along a flow path;
emitting light passing through the flow path;
sensing the light and generating a sensing signal accordingly; and
determine an operation status of the dispensing nozzle according to the sensing signal.

17. The method as claimed in claim 16, wherein the wafer stacking structure comprises a first wafer stacked over a second wafer, and dispensing the sealant toward the wafer stacking structure along the flow path further comprises:
dispensing the sealant toward a bonding interface between the first wafer and the second wafer along the flowing path substantially parallel to the carrying surface of the wafer chuck.

18. The method as claimed in claim 16, wherein determine the operation status of the dispensing nozzle according to the sensing signal further comprises:
determining the dispensing nozzle is in a normal operation status when the sensor senses a blockage of the light from the light source periodically.

19. The method as claimed in claim 16, wherein determine the operation status of the dispensing nozzle according to the sensing signal further comprises:
determining the dispensing nozzle is in an abnormal operation status when the sensor senses a constant optical intensity of the light from the light source over a predetermined period of time, or senses the light from the light source has a different intensity or pattern from a baseline intensity or pattern.

20. The method as claimed in claim 16, further comprising:
performing a thinning process on a back surface of the wafer stacking structure after the sealant is dispensed on the wafer stacking structure.
